(19) United States
(12) Patent Application Publication
(10) Pub. No.: US 2020/0174074 A1
(43) Pub. Date: Jun. 4, 2020

(54) SEMICONDUCTOR WAFER

(71) Applicant: HAMAMATSU PHOTONICS K.K., Hamamatsu-shi, Shizuoka (JP)

(72) Inventors: Motohiro SUYAMA, Hamamatsu-shi, Shizuoka (JP); Hironori TAKAHASHI, Hamamatsu-shi, Shizuoka (JP); Tomonori NAKAMURA, Hamamatsu-shi, Shizuoka (JP)

(73) Assignee: HAMAMATSU PHOTONICS K.K., Hamamatsu-shi, Shizuoka (JP)

(21) Appl. No.: 16/631,528

(22) PCT Filed: Jun. 13, 2018
(86) PCT No.: PCT/JP2018/022600

§ 371 Date: Jan. 16, 2020

(30) Foreign Application Priority Data
Jul. 18, 2017 (JP) 2017-139300

(51) Int. Cl. G01R 31/3185; G01R 31/317; H01L 23/00

(52) U.S. Cl. CPC G01R 31/318511; H01L 24/95; G01R 31/318513; G01R 31/31717

(57) ABSTRACT

There is provided a semiconductor wafer suitable for the inspection of an operation state.

A wafer is a semiconductor wafer having a plurality of chip forming regions, and includes a memory cell that is formed in each of the chip forming regions and an inspection device that is formed in each of the chip forming regions. The inspection device has a photodiode that receives an input of pump light for checking an operation of the memory cell and outputs an electrical signal corresponding to the pump light and a signal processing circuit that generates a logic signal based on the electrical signal output from the photodiode and outputs the logic signal to the memory cell.

### TECHNICAL FIELD

An aspect of the present invention relates to a semiconductor wafer.

### BACKGROUND ART

In a semiconductor manufacturing process, after forming a circuit on a semiconductor wafer, the operation state of the circuit is inspected to determine whether or not a chip (more accurately, a region that becomes a chip after dicing) is defective. The inspection of the operation state of the circuit is performed by probing, for example. In probing, the operation state of a circuit is inspected by bringing pins into contact with terminals of the circuit on a semiconductor wafer and inputting electrical signals from the pins to the terminals (for example, refer to Patent Literature 1).

### CITATION LIST

### Patent Literature

Patent Literature 1: Japanese Unexamined Patent Publication No. 2006-261218

### SUMMARY OF INVENTION

### Technical Problem

In recent years, with an increase in capacity and density of an integrated circuit, the density in the wiring rules has increased, and the number of circuits per chip in a semiconductor wafer has increased. Accordingly, the number of terminals per chip has increased. In the case of performing the above-described probing on such a semiconductor wafer, an increase in the number of pins increases the pressing force (pressing force on the semiconductor wafer) when the pins are brought into contact with the terminals of the circuit. This may cause damage to the semiconductor wafer.

An aspect of the present invention has been made in view of the above circumstances, and an object thereof is to provide a semiconductor wafer suitable for the inspection of an operation state.

### Solution to Problem

A semiconductor wafer according to one aspect of the present invention is a semiconductor wafer having a plurality of chip forming regions, and includes: an internal circuit that is formed in each of the chip forming regions; and an inspection device that is formed in each of the chip foiming regions. The inspection device has: a light receiving element that receives an input of a first optical signal for checking an operation of the internal circuit and outputs an electrical signal corresponding to the first optical signal; and a signal processing circuit that generates a logic signal based on the electrical signal output from the light receiving element and outputs the logic signal to the internal circuit.

In the semiconductor wafer according to one aspect of the present invention, as the inspection device, the light receiving element that outputs an electrical signal corresponding to an optical signal and the signal processing circuit that generates a logic signal based on the electrical signal are provided. Since the signal for checking the operation of the internal circuit is input as an optical signal, it is not necessary to bring a pin for signal input into contact with the terminal of a circuit when inspecting the operation state. For this reason, in an aspect in which the pin for signal input is brought into contact with the terminal of the circuit, an increase in the pressing force on the semiconductor wafer, which has been a problem when checking the operation state of a high-density integrated circuit, does not become a problem. Then, a logic signal is generated by the signal processing circuit based on the electrical signal output from the light receiving element, and the logic signal is input to the internal circuit. Accordingly, even in an aspect in which the signal for operation check is input as an optical signal, the operation of the internal circuit is appropriately checked as in the conventional aspect in which the pin is brought into contact with the terminal. In addition, in the aspect in which the pin for signal input is brought into contact with the terminal of the circuit, when checking the operation of a high-density integrated circuit, it is necessary to bring pins into contact with densely provided teiiiiinals with high accuracy. For this reason, pin tips need be made fine, but there has been a limitation in physically reducing the pin tips. As a result, there is a possibility that it is not possible to cope sufficiently with an increase in the density of the integrated circuit. In this regard, in the inspection of the operation state of the semiconductor wafer according to one aspect of the present invention, the signal for operation check is input as an optical signal, and accordingly, the shape of the pin tip does not become a problem when checking the operation. As described above, according to one aspect of the present invention, it is possible to provide a semiconductor wafer suitable for the inspection of the operation state. In addition, in the aspect in which the pin for signal input is physically in contact with the terminal of the circuit, there is an upper limit (for example, several hundred MHz) in the frequency band of the signal that can be supplied by the pin. Depending on the upper limit, there is a case where it is not possible to respond to a high-speed input signal. In this regard, in the case of inspecting the operation state using the semiconductor wafer according to one aspect of the present invention, the signal for operation check is supplied not by physical contact of pins but by input of an optical signal. Therefore, it is possible to supply a signal in a frequency band exceeding the above-described upper limit as a signal for operation check. In addition, in the semiconductor wafer according to one aspect of the present invention, since the above-described inspection device is formed in the chip forming region, a wiring for electrically connecting the light receiving element and the like to the input and output terminals formed on the chip can be shortened. As a result, a semiconductor wafer more suitable as a semiconductor for which operation state inspection is to be performed is provided.

The semiconductor wafer described above may further include: an input terminal that is formed in each of the chip forming regions to input an input signal to the internal circuit; and an output terminal that is formed in each of the chip forming regions to output an output signal from the internal circuit, and each of the input terminal and the output terminal may be configured to include a through electrode that penetrates the semiconductor wafer in a thickness direction. Since the input and output terminals are configured to include through electrodes, a plurality of chips can be connected to each other without using wire bonding or the like in a configuration in which the plurality of chips are stacked. Thus, the chip on which through electrodes are formed is significant in terms of the number of wirings, such as wire bonding. In the semiconductor wafer according to one aspect of the present invention, as described above, since the inspection device is also formed in the chip forming region, a wiring such as wire bonding relevant to the inspection device can be shortened. Therefore, the effect of the configuration of the semiconductor in which chips are stacked using the through electrodes can be more noticeably achieved. That is, by adopting the configuration in which the inspection device is provided in the chip forming region and, the input and output terminals include the through electrodes, the effect of shortening the wiring such as wire bonding can be more noticeably achieved.

The semiconductor wafer described above may further include an output terminal that is formed in each of the chip forming regions to output an output signal from the internal circuit, and the inspection device may further have a switch unit that is electrically connected to the output terminal and outputs a signal corresponding to the output signal while a second optical signal is being input. Thus, since the switch unit that outputs a signal corresponding to the output signal is provided, it is possible to detect a signal relevant to the inspection of the operation state of the internal circuit, without bringing a pin into contact with the output terminal itself, by detecting the signal from the switch unit. This further suppresses an increase in the pressing force on the semiconductor wafer, which is a problem in the aspect in which pins are brought into contact with terminals. That is, by adopting the configuration in which the switch unit is provided, it is possible to provide a semiconductor wafer more suitable for the inspection of the operation state. In addition, for example, in a case where the second optical signal is pulsed light, the signal itself output from the switch unit is a signal having a narrow frequency band. For this reason, even in a case where the logic signal is a high-speed signal and the band of the output signal output from the output terminal is wide, the signal relevant to the inspection of the operation state of the internal circuit (signal output from the switch unit) can be easily detected using a probe pin or the like. That is, by adopting the configuration in which the switch unit is provided, even in a case where a high-speed signal is input, the operation state of the internal circuit is appropriately inspected using a simple configuration capable of detecting only a narrow band signal, such as a probe pin.

In the semiconductor wafer described above, the signal processing circuit may have: an amplifier that amplifies the electrical signal output from the light receiving element at a predetermined amplification degree; and a discriminator that generates the logic signal based on the electrical signal amplified by the amplifier and outputs the logic signal to the internal circuit. Therefore, in a case where the amount of light received by the light receiving element is equal to or greater than a predetermined amount, a configuration in which a logic signal that is High is input to the internal circuit can be easily realized by setting the amplification degree of the amplifier and the threshold value of the discriminator. As a result, a semiconductor wafer more suitable as a semiconductor wafer for which operation state inspection is to be performed is provided.

The semiconductor wafer described above may further include an input terminal that is foiiiied in each of the chip forming regions to input an input signal to the internal circuit, and the signal processing circuit may be connected to the internal circuit through a wiring that bypasses the input terminal so that the logic signal is input to the internal circuit without passing through the input terminal. According to such a configuration, when checking the operation of the internal circuit, the capacity of the input terminal is not a problem, and a high-speed electrical signal can be easily input to the internal circuit.

### Advantageous Effects of Invention

According to one aspect of the present invention, it is possible to provide a semiconductor wafer suitable for the inspection of the operation state.

### BRIEF DESCRIPTION OF DRAWINGS

FIG. 1 is a schematic perspective view illustrating a wafer inspection apparatus according to a first embodiment.

FIG. 2 is a schematic plan view of a wafer as viewed from the device forming region side.

FIG. 3 is a schematic plan view of one chip forming region and a dicing street around the chip forming region as viewed from the device forming region side.

FIG. 4 is a schematic cross-sectional view of a wafer relevant to the formation region of a photodiode.

FIG. 5 is a block diagram illustrating the electrical connection of each device.

FIG. 6 is a flowchart of a semiconductor manufacturing method according to the first embodiment.

FIG. 7 is a schematic plan view of a silicon substrate before device formation.

FIG. 8 is a flowchart of an inspection step in the semiconductor manufacturing method.

FIG. 9 is a schematic perspective view illustrating a wafer inspection apparatus according to a second embodiment.

FIG. 10 is a diagram of the reflection of probe light in a nonlinear optical crystal disposed on an output terminal.

FIG. 11 is a flowchart of a semiconductor manufacturing method according to the second embodiment.

FIG. 12 is a schematic diagram of a wafer inspection apparatus according to a third embodiment.

FIG. 13 is a diagram for explaining a change in reflectance according to expansion and contraction of a depletion layer.

FIG. 14 is a flowchart of a semiconductor manufacturing method according to the third embodiment.

FIG. 15 is a block diagram illustrating the electrical connection of each device in a modification example.

### DESCRIPTION OF EMBODIMENTS

### First embodiment

Hereinafter, a first embodiment of the present invention will be described in detail with reference to the accompanying diagrams. In addition, in the description, the same reference numerals are used for the same elements or elements having the same functions, and repeated description thereof will be omitted.

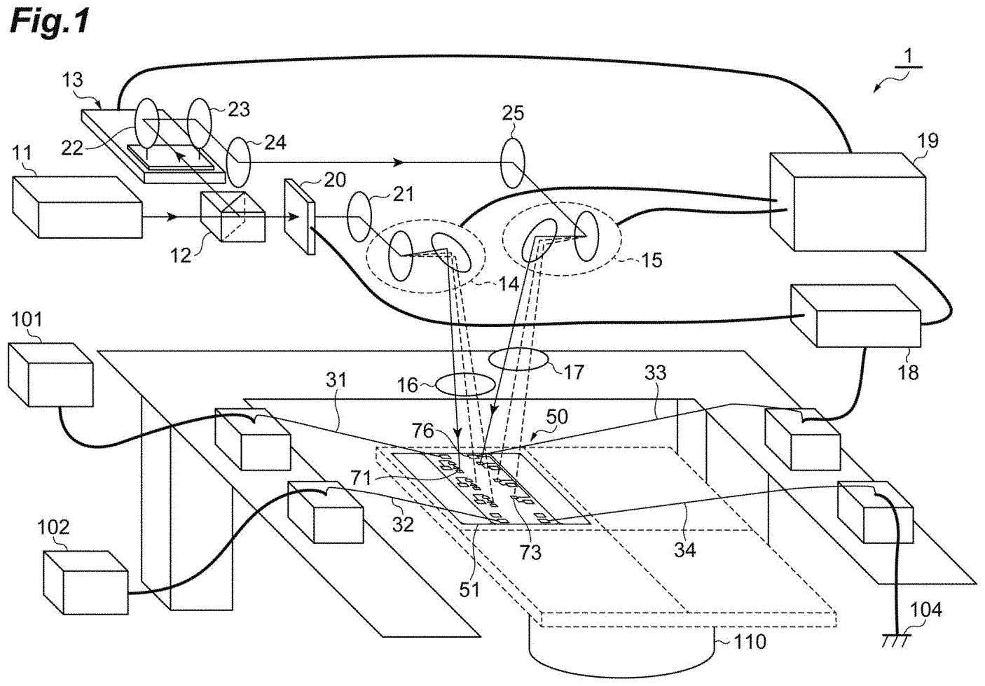

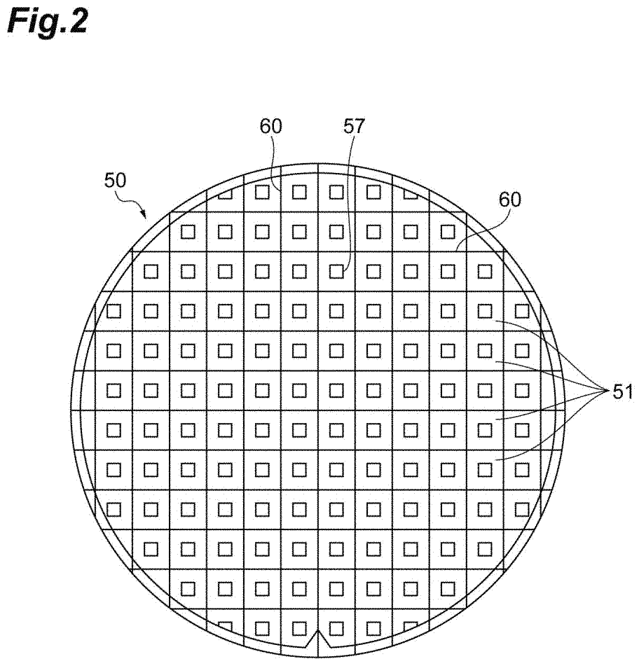

FIG. 1 is a schematic perspective view illustrating a wafer inspection apparatus 1 according to a first embodiment. The wafer inspection apparatus 1 illustrated in FIG. 1 is an apparatus for inspecting the operation state of an internal circuit formed in a chip forming region 51 of a wafer 50 (semiconductor wafer). First, the wafer 50 that is an inspection target of the wafer inspection apparatus 1 will be described with reference to FIGS. 2 to 5.

[Wafer]

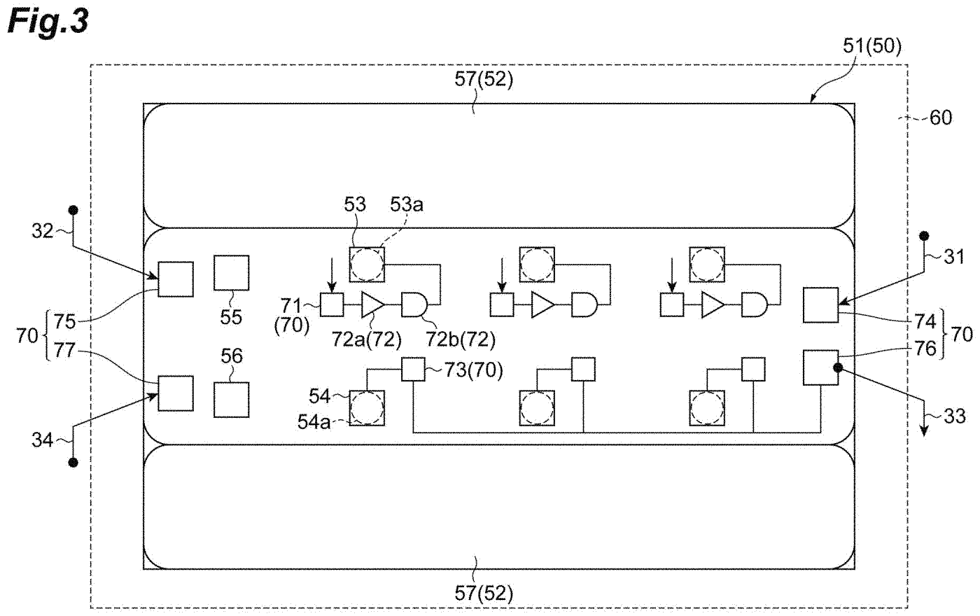

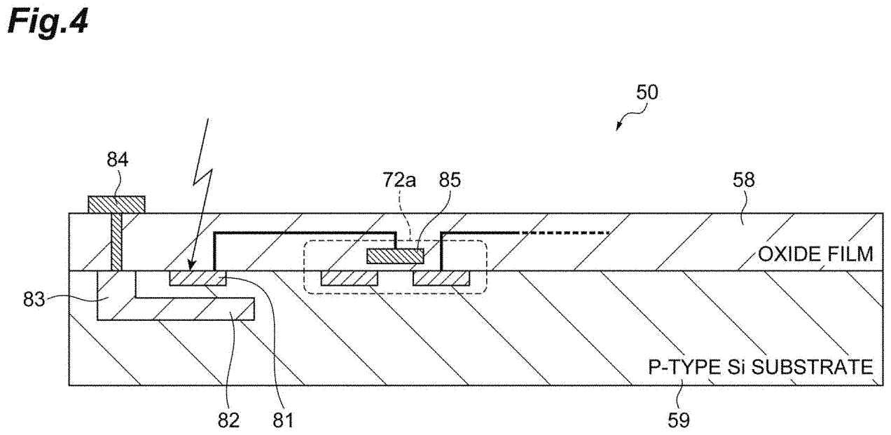

FIG. 2 is a schematic plan view of the wafer 50 as viewed from the device forming region side. The device forming region is a region of a main surface of a silicon substrate 59 (refer to FIG. 4) included in the wafer 50, and is a region where various devices such as an inspection device 70 (refer to FIG. 3), which will be described later, are formed. In addition, in FIG. 2, the inspection device 70 is not illustrated. As illustrated in FIG. 2, the wafer is approximately circular in plan view, and has a plurality of chip forming regions 51 that are approximately rectangular in plan view. The chip forming region 51 is a region that becomes a chip after dicing. After the operation state of a memory cell 57 that is an internal circuit of the chip forming region 51 is inspected by the wafer inspection apparatus 1 described above, a plurality of chips are generated from the wafer 50 by performing dicing along a dicing street 60 for each chip forming region 51.

FIG. 3 is a schematic plan view of one chip forming region 51 and the dicing street 60 around the chip forming region 51, which are included in the wafer 50, as viewed from the device forming region side. As illustrated in FIG. 3, as components formed in the chip forming region 51, the wafer 50 includes a memory block 52 including the memory cell 57, an input terminal 53, an output terminal 54, a power supply terminal 55, a ground terminal 56, and a photodiode 71 (light receiving element), a signal processing circuit 72, a photo conductive antenna (PCA) 73 (switch unit), and pads 74, 75, 76, and 77 that are inspection devices 70. That is, in the wafer 50, all components of the inspection device 70 are formed not outside the chip forming region, such as the dicing street 60, but inside the chip forming region 51. The width of the dicing street 60 (that is, the width of the cutting allowance in dicing) is, for example, about 25 μm.

The memory block 52 has a plurality of memory cells 57 (internal circuits). The memory cell 57 is a memory circuit, such as a dynamic random access memory (DRAM), a static random access memory (SRAM), and a flash electrically erasable programmable read-only memory (EEPROM), for example. The memory cell 57 is configured to include a MOS transistor, a capacitance element for information storage, and the like. A plurality of input terminals 53 are provided according to the number of memory cells 57, for example. In addition to the plurality of memory cells 57, the memory block 52 may have components of other circuit elements (semiconductor elements), word lines, bit lines, sense amplifiers, fuses, and the like. Although the arrangement region of the memory block 52 is not limited, in the example illustrated in FIG. 3, a pair of memory blocks 52 are disposed at both ends with the inspection device 70 and the like, which are provided near the center, interposed therebetween.

The input terminal 53 is an input terminal for inputting an input signal to the memory cell 57 or the like that is an internal circuit. The output terminal 54 is an output terminal for outputting an output signal from the memory cell 57 or the like that is an internal circuit. The input terminal 53 includes a through electrode 53a that penetrates the wafer 50 in the thickness direction. Similarly, the output terminal 54 includes a through electrode 54a that penetrates the wafer 50 in the thickness direction. The input terminal 53 and the output terminal 54 are formed of, for example, conductive metal such as aluminum. The input terminal 53 and the output terminal 54 are provided so as to be associated with each other. In addition, in FIG. 3, for convenience of explanation, three input terminals 53 and three output terminals 54 are shown. In practice, however, about several tens to several thousands of input terminals 53 and output terminals 54 may be disposed. In addition, in FIG. 3, for convenience of explanation, the column of the input terminals 53 and the column of the output terminals 54 are shown so as to be distinguished from each other. In practice, however, the input terminals 53 and the output terminals 54 may be randomly disposed without the column of the input terminals 53 and the column of the output terminals 54 being distinguished from each other. In addition, the same terminal may have both functions of the input terminal 53 and the output terminal 54.

The photodiode 71 receives pump light (first optical signal) for checking the operation of the memory cell 57 or the like that is an internal circuit and converts the light and darkness of the pump light into an electrical signal, and outputs the electrical signal to the signal processing circuit 72. The above-described pump light is output from a light source 11 of the wafer inspection apparatus 1 illustrated in FIG. 1 (details will be described later). A plurality of photodiodes 71 are provided so as to correspond to a plurality of input terminals 53 in a one-to-one manner. Thus, in the present embodiment, a signal for operation check is supplied to the internal circuit through the photodiode 71 by the optical signal (pump light). Therefore, the signal for operation check can be supplied to the internal circuit in a non-contact manner without pin contact. The upper limit of the frequency band of the photodiode 71 is, for example, 10 GHz or more. In addition, although the present embodiment is described on the assumption that the photodiode 71 corresponds to the input terminal 53 in a one-to-one manner, the photodiode and the input terminal may not correspond to each other in a one-to-one manner without being limited thereto.

The signal processing circuit 72 generates a logic signal based on the electrical signal output from the photodiode 71, and outputs the logic signal to an internal circuit such as the memory cell 57. The signal processing circuit 72 is configured to include, for example, an amplifier 72a and a discriminator 72b. The amplifier 72a is an operational amplifier that amplifies the electrical signal output from the photodiode 71 at a predetermined amplification degree. The discriminator 72b converts the electrical signal into a logic signal indicated by High or Low according to whether the electrical signal amplified by the amplifier 72a exceeds a predetermined threshold value. In the amplifier 72a and the discriminator 72b, the amplification degree and the threshold value are set such that High is obtained in a case where the amount of light received by the photodiode 71 is equal to or greater than a predetermined value.

The electrical connection between the photodiode 71 and the amplifier 72a described above will be described with reference to FIG. 4. FIG. 4 is a schematic cross-sectional view of the wafer 50 relevant to the formation region of the photodiode 71. In addition, FIG. 4 shows only a part of the configuration of the wafer 50, such as the photodiode 71 and the amplifier 72a, and other components are omitted. As illustrated in FIG. 4, the photodiode 71 and the amplifier 72a are formed on the main surface of the silicon substrate 59. In the wafer 50, an oxide film 58 as an insulating layer is formed on the main surface of the silicon substrate 59 formed of silicon crystal. The photodiode 71 forms a so-called PIN photodiode.

The photodiode 71 is configured to include an n-type impurity layer 81, a p-type impurity layer 82, a p-type impurity layer for connection 83, and an electrode 84. The n-type impurity layer 81 is a semiconductor layer that is formed in a shallow region of the main surface of the silicon substrate 59 and includes high-concentration n-type impurities. The shallow region is, for example, a region having a depth of about 0.1 μm. The n-type impurities are, for example, antimony, arsenic, phosphorus, or the like. The high concentration is, for example, an impurity concentration of about 1×10¹⁷ cm⁻³ or more. The n-type impurity layer 81 functions as a part of a photosensitive region that receives incident pump light. The p-type impurity layer 82 is a semiconductor layer that is formed in a deep region of the main surface of the silicon substrate 59 and includes high-concentration p-type impurities. The deep region is, for example, a region whose central region has a depth of about 3 μm. In addition, the region where the n-type impurity layer 81 is formed and the region where the p-type impurity layer 82 is formed may be formed so as to be separated from each other by about 2 μm. The p-type impurities are, for example, boron. The p-type impurity layer for connection 83 is a semiconductor layer that is formed between the p-type impurity layer 82 and the electrode 84 in order to electrically connect the p-type impurity layer 82 and the electrode 84 to each other. The electrode 84 is an electrode for inputting a predetermined voltage (for example, 2 V) in the photodiode 71. The electrode 84 is formed of, for example, conductive metal such as aluminum. The n-type impurity layer 81 of the photodiode 71 is electrically connected to a gate 85 of a field effect transistor (FET) forming the amplifier 72a, and the electrical signal output from the photodiode 71 is input to the gate 85 of the FET.

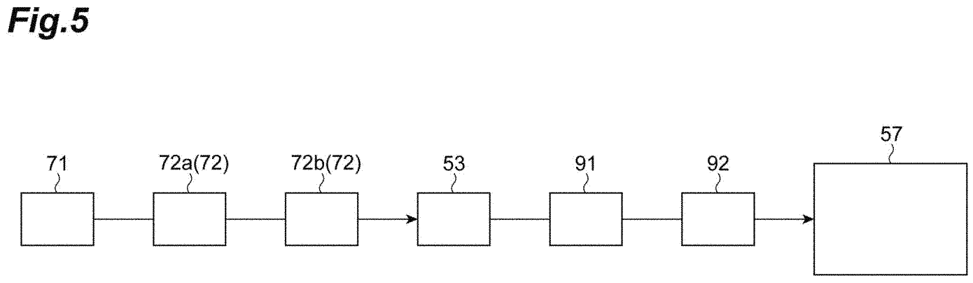

Details of the transmission path of the electrical signal from the photodiode 71 to the memory cell 57 will be described with reference to FIG. 5. FIG. 5 is a block diagram illustrating electrical connection of each device relevant to the transmission path of the electrical signal. As illustrated in FIG. 5, the electrical signal output from the photodiode 71 based on the pump light is amplified by the amplifier 72a at a predetermined amplification degree and then input to the discriminator 72b, and is output from the discriminator 72b as a logic signal and input to the input terminal 53. The logic signal output from the input terminal 53 is input to the memory cell 57 through an electro-static discharge (ESD) prevention circuit 91 and a signal buffer circuit 92. The ESD prevention circuit 91 is a circuit for preventing a surge voltage due to electrostatic discharge. The ESD prevention circuit 91 has a function of releasing the surge voltage that has entered from the input terminal 53 to the ground. The signal buffer circuit 92 is a circuit that outputs an input logic signal (digital signal) as it is, and is provided to speed up signal transmission (improve the driving capability of a logic signal).

Returning to FIG. 3, the PCA 73 is electrically connected to the output terminal 54, and probe light (second optical signal) is input to the PCA 73. Only while the probe light is being input, a measurement signal that is a signal corresponding to the output signal output from the output terminal 54 (output signal output from the output terminal 54 in response to the input of a logic signal to the memory cell 57 or the like) is output. The probe light is output from the light source of the wafer inspection apparatus 1 illustrated in FIG. 1 (details will be described later). The PCA 73 is a photoconductive switch that is often used for terahertz generation and detection. In addition, instead of the PCA 73, a photodiode for high-speed signals may be used. A plurality of PCAs 73 are provided so as to correspond to a plurality of output terminals 54 in a one-to-one manner. The PCA 73 is electrically connected to the corresponding pad 76 in a one-to-one manner. The measurement signal output from the PCA 73 is input to the pad 76.

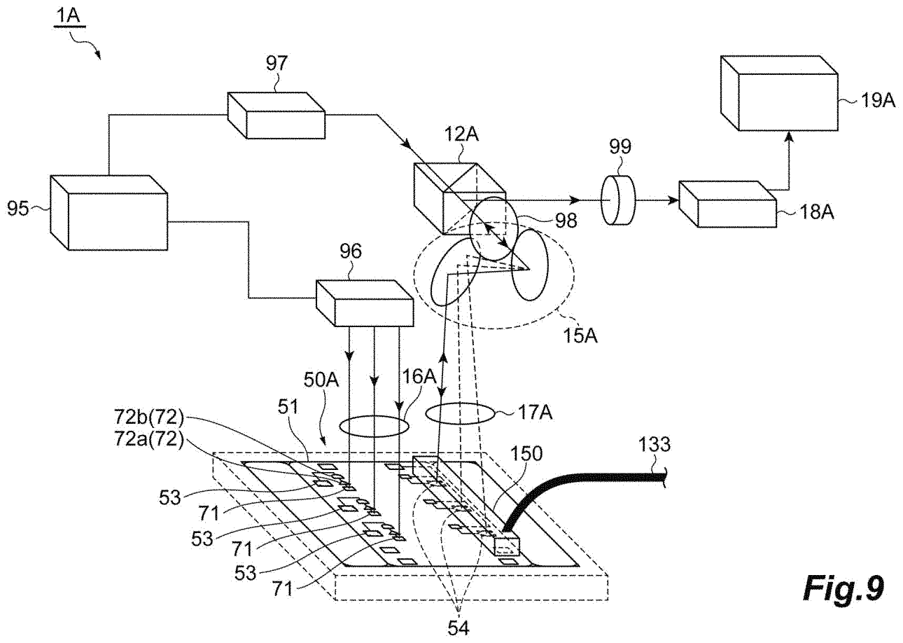

The pads 74, 75, 76, and 77 are terminals for pin contact. The pad 74 is a terminal in contact with a pin 31 for supplying power to the signal processing circuit 72. The pad 75 is a terminal in contact with a pin 32 for supplying power to the wafer 50 to be inspected. The pad 76 is a terminal in contact with a pin 33 for outputting the signal from the PCA 73, and the same number of pads 76 as the number of PCAs 73 are provided so as to correspond to the PCAs 73 in a one-to-one manner. In addition, as illustrated in FIG. 9, one pad 76 may be provided for all the PCAs 73 instead of corresponding to the PCAs 73 in a one-to-one manner. In this case, the probe readout results are combined into one and output from one pin 33 to a lock-in amplifier 18. In this manner, since the number of pins 33 can be reduced, the load applied to the wafer 50 from the pin 33 can be reduced. The pad 77 is a terminal in contact with a pin 34 for ground connection.

[Wafer Inspection Apparatus]

Next, the wafer inspection apparatus 1 according to the first embodiment will be described with reference to FIG. 1. The wafer inspection apparatus 1 inspects the operation state of an internal circuit, such as the memory cell 57 in the chip forming region 51, by emitting pump light to the photodiode 71 of the wafer 50 and emitting probe light to the PCA 73 using a so-called pump probe method. The pump probe method is measurement means for verifying a phenomenon in the time domain of ultra-high speed (femtosecond to picosecond), and excites the wafer 50 with pump light and observes the operation state of the wafer 50 with probe light. In the pump probe method, by generating probe light synchronized with pump light and delaying the incidence timing of the probe light with respect to the incidence timing of the pump light, and changing the delay time, observation from the start to the end of the light reaction is possible. The wafer inspection apparatus 1 has the light source 11, a beam splitter 12, an optical delay device 13, optical scanners 14 and 15, condensing lenses 16 and 17, the lock-in amplifier 18, and a control and analysis device 19.

The light source 11 is a light source that is operated by a power supply (not illustrated), and outputs pulsed light that is emitted to the wafer 50. The light source 11 is, for example, a femtosecond pulsed laser light source. As the femtosecond pulsed laser light source, for example, a transmitter (for example, a titanium sapphire laser transmitter) that generates an optical pulse with a wavelength of about 800 nm, a pulse width of about 100 fs, and an output of about 100 mW at a repetition frequency of 100 MHz can be used. Thus, the light source 11 outputs pulsed light that is continuously output in a predetermined cycle. The light output from the light source 11 is input to the beam splitter 12. In addition, the light output from the light source 11 may be input to a neutral density filter and attenuated before being input to the beam splitter 12.

The beam splitter 12 transmits a part of the light output from the light source 11 as it is and reflects the remaining light in a direction approximately perpendicular to the transmission direction. The light transmitted through the beam splitter 12 becomes the above-described pump light and is input to an optical chopper 20, and the reflected light becomes the above-described probe light and is input to the optical delay device 13. Both the pump light and the probe light are pulsed light output from the light source 11 and are synchronized with each other. The optical chopper 20 periodically chops the pump light by switching the pump light at fixed periods. The optical chopper 20 is configured as, for example, a rotating disk in which a portion that transmits the pump light and a portion that does not transmit the pump light are alternately disposed, and periodically transmits the pump light by being rotated by the rotational driving of a motor. By providing the optical chopper 20 and performing measurement with the lock-in amplifier 18, it is possible to improve the SN ratio of the signal. The pump light transmitted through the optical chopper 20 is reflected in the direction of the optical scanner 14 by a reflecting plate 21.

The optical scanner 14 is configured by an optical scanning element, such as a galvano mirror or a micro electro mechanical systems (MEMS), for example. The optical scanner 14 emits the pump light according to the control signal from the control and analysis device 19 so that the pump light is emitted to a predetermined emission area (specifically, the arrangement location of each photodiode 71). The optical scanner 14 has a configuration for two-dimensionally emitting the pump light to the predetermined emission area. For example, the optical scanner 14 has two motors, a mirror attached to each motor, a driver for driving the motor, an interface for receiving the control signal from the control and analysis device 19, and the like. The pump light emitted by the optical scanner 14 is emitted to the arrangement location of the photodiode 71 through the condensing lens 16. For example, the optical scanner 14 continuously sets one or a plurality of photodiodes 71 as emission targets so that the pump light is emitted to each photodiode 71 in a sequential manner. The condensing lens 16 is a lens for condensing the pump light at the arrangement location of the photodiode 71, and is, for example, an objective lens.

The optical delay device 13 changes the delay time of the probe light by changing the incidence timing of the probe light to the PCA 73. The delay time of the probe light is a delay time of the incidence timing of the probe light to the PCA 73 with respect to the incidence timing of the pump light to the photodiode 71. The optical delay device 13 changes the delay time of the probe light. The optical delay device 13 changes the delay time of the probe light, for example, by changing the optical path length of the probe light. The optical delay device 13 is configured by an optical system including movable mirrors 22 and 23. The movable mirrors 22 and 23 are a pair of reflecting minors disposed obliquely at an angle of, for example, 45° with respect to the incidence optical axis in the optical delay device 13. The probe light is reflected by the movable mirror 22 in a direction perpendicular to the incidence optical axis and is incident on the movable mirror 23, and is reflected by the movable mirror 23 in a direction parallel to the incidence optical axis. The movable minors 22 and 23 are provided on a movable base in the optical delay device 13, and are configured to be movable in the incidence optical axis direction by the optical delay device 13 by a motor driven according to the control signal from the control and analysis device 19. As the movable mirrors 22 and 23 move to the above incidence optical axis direction, the optical path length of the probe light changes. That is, the optical path length of the probe light increases as the movable mirrors 22 and 23 move away from the beam splitter 12 in the incidence optical axis direction, and the optical path length of the probe light decreases as the movable mirrors 22 and 23 move closer to the beam splitter 12 in the incidence optical axis direction. The probe light output from the movable mirror 23 is reflected by the reflecting plate 24, and the probe light reflected by the reflecting plate 24 is further reflected in the direction of the optical scanner 15 by the reflecting plate 25.

The optical scanner 15 is configured by an optical scanning element, such as a galvano mirror or a micro electro mechanical systems (MEMS), for example. The optical scanner 15 emits probe light according to the control signal from the control and analysis device 19 so that the probe light is emitted to a predetermined emission area (specifically, the arrangement location of each PCA 73). The optical scanner 15 has a configuration for two-dimensionally emitting the probe light to the predetermined emission area. For example, the optical scanner 15 has two motors, a mirror attached to each motor, a driver for driving the motor, an interface for receiving the control signal from the control and analysis device 19, and the like. The probe light emitted by the optical scanner 15 is emitted to the arrangement location of the PCA 73 through the condensing lens 17. For example, the optical scanner 15 continuously sets one or a plurality of PCAs 73 as emission targets so that the probe light is emitted to each photodiode 71 in a sequential manner. The condensing lens 17 is a lens for condensing the probe light at the arrangement location of the PCA 73, and is, for example, an objective lens.

As described above, the PCA 73 outputs a measurement signal, which is a signal corresponding to the output signal output from the output teiiiiinal 54, to the pad 76 only while the probe light is being input. For example, in a case where the probe light is pulsed light of 20 ps, the output (measurement signal) of the output terminal 54 is input to the pad 76 only in the time width of 20 ps. Thus, the PCA 73 is in an ON state (a state in which a measurement signal is output) only for a short period based on the pulsed light. Then, by changing the incidence timing of the probe light to the PCA 73 using the optical delay device 13, a high-speed output pulse (output signal that is output from the output terminal 54) is output while performing sampling. As a result, the output signal can be observed with a good SN ratio. The measurement signal (probe signal) sampled and output in this manner is measured in a direct current manner, and can be read out by the pin 33 brought into contact with the pad since its frequency band is narrow. The measurement signal read by the pin 33 is input to the lock-in amplifier 18.

For the purpose of improving the SN ratio of the measurement signal read out by the pin 33, the lock-in amplifier 18 amplifies and outputs only a signal, which matches the repetition frequency at which the pump light is periodically chopped by the optical chopper 20, in the measurement signal. The signal (amplified signal) output by the lock-in amplifier 18 is input to the control and analysis device 19.

The control and analysis device 19 is, for example, a computer such as a PC. For example, an input device such as a keyboard and a mouse for inputting measurement conditions and the like from a user and a display device such as a monitor showing the user a measurement result and the like are connected to the control and analysis device 19 (both not illustrated). The control and analysis device 19 includes a processor. Using the processor, the control and analysis device 19 executes, for example, a function of controlling the light source 11, the optical delay device 13, the optical scanners 14 and 15, and the lock-in amplifier 18 and a function of performing analysis such as generating a waveform (analysis image) based on the amplified signal from the lock-in amplifier 18. The user can determine whether or not a chip on which devices are formed is defective (whether or not the chip is a defective product) based on the analysis image generated by the control and analysis device 19, for example.

[Semiconductor Manufacturing Method]

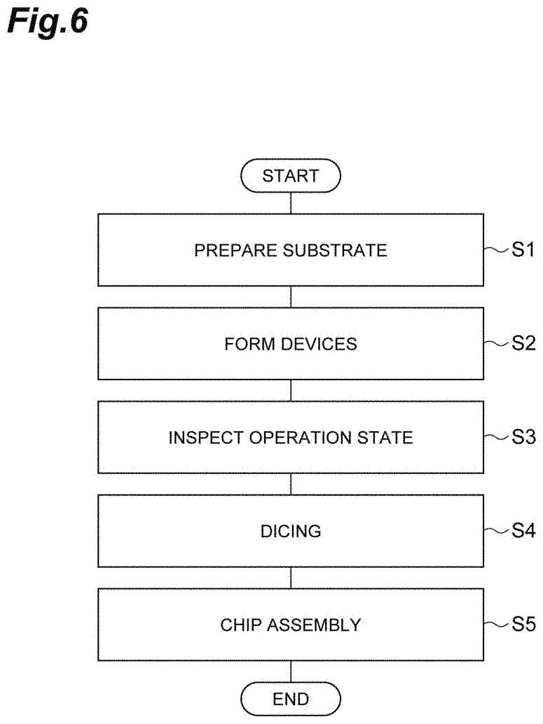

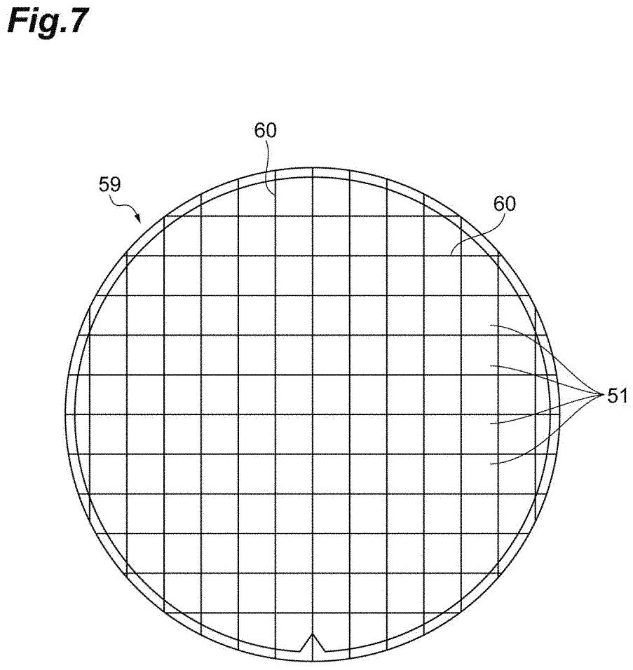

Next, an example of a semiconductor manufacturing method including an inspection step using the wafer inspection apparatus 1 described above will be described with reference to the flowchart of FIG. 6. First, the silicon substrate 59 is prepared (step S1: preparation step). In the preparation step, as illustrated in FIG. 7, the silicon substrate 59 on which devices, such as the memory cell 57 and the inspection device 70, are not formed is prepared. As illustrated in FIG. 7, the prepared silicon substrate 59 is approximately circular in plan view. The silicon substrate 59 has a plurality of chip forming regions 51 that are approximately rectangular in plan view. The chip forming region 51 is a region that becomes a chip by dicing along the dicing street 60 after device formation.

Then, each device is formed in the device forming region of the silicon substrate 59 (step S2: forming step). In the forming step, as illustrated in FIG. 3, the memory block 52 including a plurality of memory cells 57, a plurality of photodiodes 71 that receive pump light for checking the operations of the memory cells 57 and output electrical signals, and the signal processing circuit 72 that generates a logic signal based on the electrical signals and outputs the logic signal to the memory cells 57 are formed in each chip forming region 51 of the wafer 50 having a plurality of chip forming regions 51.

Then, pump light is input to the photodiode 71 to inspect the operation state of the memory cell 57 (step S3: inspection step). In the inspection step, probe light is further input to a region corresponding to the output terminal 54, so that a signal (measurement signal) corresponding to the output signal output from the output terminal 54 in nresponse to the input of a logic signal to the memory cell 57 is detected to inspect the operation state of the memory cell 57. More specifically, in the inspection step, the probe light synchronized with the pump light is repeatedly input to the PCA 73 while changing the delay time with respect to the input timing of the pump light to the photodiode 71, and the measurement signal output from the PCA 73 is detected to inspect the operation state of the memory cell 57. Thus, in the inspection step, the probe light synchronized with the pump light, which is pulsed light continuously output in a predetermined cycle, is delayed by a predetermined delay time with respect to the input timing of the pump light to the photodiode 71 and input to the PCA 73, and the delay time is changed to detect the measurement signal that is output from the PCA 73 in response to the input of each pulse of the probe light.

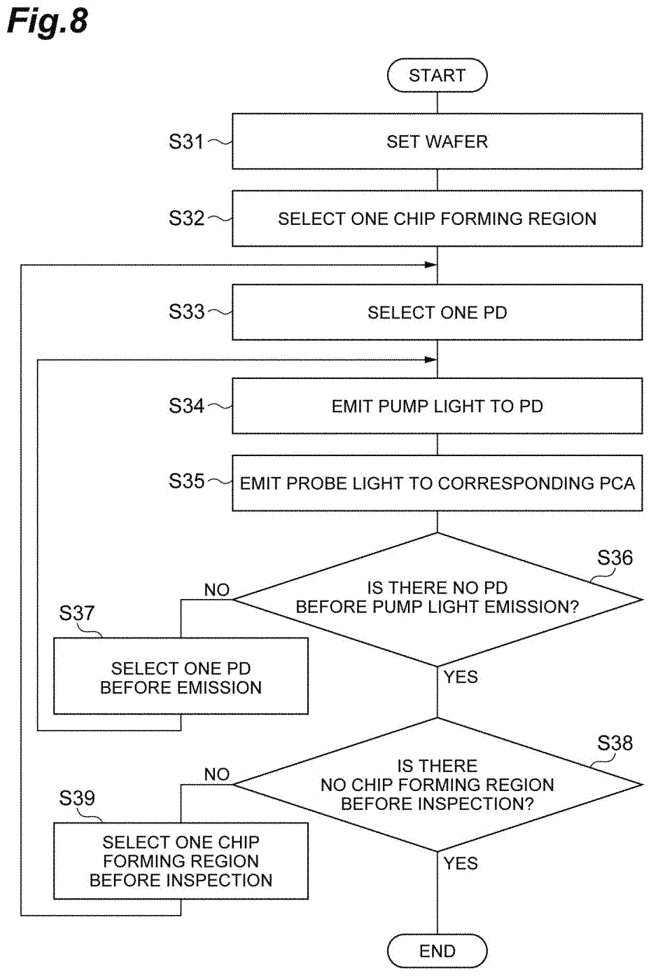

Details of the inspection step will be described in more detail with reference to the flowchart of FIG. 8 and FIG. 1. In the inspection step, as illustrated in FIG. 8, first, the wafer 50 is set on an inspection table 110 (refer to FIG. 1) of the wafer inspection apparatus 1 (step S31). The wafer 50 set on the inspection table 110 is the wafer 50 on which devices are formed in the forming step of step S2. In addition, the wafer 50 in FIG. 1 is rectangular in plan view. In practice, however, the wafer 50 may be circular in plan view as illustrated in FIG. 2.

Then, one chip forming region 51 is selected from the plurality of chip forming regions 51 included in the wafer 50 placed on the inspection table 110 (step S32). Specifically, for example, when an instruction to start inspection is received from the user, the control and analysis device 19 specifies the chip forming region 51 at a predetermined position set in advance as the chip forming region 51 to be inspected first. When the chip forming region 51 to be inspected is specified, as illustrated in FIG. 3, the pin 31 is brought into contact with the pad 74 of the chip forming region 51, the pin 32 is brought into contact with the pad 75, the pin 33 is brought into contact with each pad 76, and the pin 34 is brought into contact with the pad 77. As illustrated in FIG. 1, the pin 31 is electrically connected to a power supply unit 101 for the signal processing circuit 72, the pin 32 is electrically connected to a power supply unit 102 for the wafer 50, a plurality of pins 33 are electrically connected to the lock-in amplifier 18, and the pin 34 is electrically connected to a ground 104. In addition, the aspect of supplying power to the wafer 50 is not limited to the above. For example, a photodiode and a power supply voltage forming circuit may be formed on the wafer, and light may be emitted to the photodiode to supply electric power in a non-contact manner, or electric power may be supplied in a spatial transmission manner using an electromagnetic field.

Then, one photodiode 71 is selected from the plurality of photodiodes 71 in the selected chip forming region 51 (step S33). Specifically, the control and analysis device 19 specifies the photodiode 71 at a predetermined position set in advance as the photodiode 71 on which the pump light is incident first.

Then, the pump light is emitted to the selected photodiode 71 (step S34). Specifically, the control and analysis device 19 controls the optical scanner 14 so that the pump light is emitted to the photodiode 71 in the selected chip forming region 51, and controls the light source 11 so that a femtosecond pulsed laser is output from the light source 11.

Then, the probe light is emitted to the PCA 73 corresponding to the selected photodiode 71 (step S35). The PCA 73 corresponding to the photodiode 71 is the PCA 73 electrically connected to the photodiode 71. Specifically, the control and analysis device 19 controls the optical scanner 15 so that the probe light is emitted to the PCA 73 corresponding to the selected photodiode 71. In addition, the control and analysis device 19 controls the optical delay device 13 so that the probe light is repeatedly input to the PCA 73 while changing the delay time with respect to the pump light. The measurement signal sampled in this manner is input to the lock-in amplifier 18 through the pin 33. In addition, an amplified signal obtained by amplifying the measurement signal is input from the lock-in amplifier 18 to the control and analysis device 19, and the control and analysis device 19 analyzes the amplified signal. Specifically, the control and analysis device 19 generates an analysis image based on the amplified signal. For example, after the end of the inspection of all the chip forming regions 51 of the wafer 50, the user can check whether or not the operation state of the region of the inspected memory cell 57 (region of the memory cell 57 relevant to the selected chip forming region 51) is a normal state based on the analysis image. In addition, whether or not the operation state of each chip forming region 51 is normal (non-defective) may be determined by the control and analysis device 19 without depending on the user. In this case, for example, an analysis result (image pattern) in the case of a non-defective product is prepared in advance, so that the control and analysis device 19 determines whether or not the product is non-defective. The control and analysis device 19 stores the position infoiiiiation of the chip forming region 51 determined to be non-defective by the user or by the control and analysis device 19.

Then, it is determined whether or not the photodiode 71 before pump light emission is present in the selected chip forming region 51 (step S36). Since the number of photodiodes 71 in each chip forming region 51 can be grasped in advance, the control and analysis device 19 deteimines whether or not the photodiode 71 before pump light emission is present based on whether or not pump light emission corresponding to the number of photodiodes 71 in one chip forming region 51 has been performed, for example.

In a case where it is determined that the photodiode 71 before pump light emission is present in the selected chip forming region 51 in step S36 (S36: NO), one photodiode 71 before the pump light emission is selected (step S37). Specifically, the control and analysis device 19 specifies the photodiode 71, on which the pump light is to be incident next, according to a predetermined selection order. Thereafter, the processing of steps S34 to S36 described above is perfoiiiied again.

On the other hand, in a case where it is determined that the photodiode 71 before pump light emission is not present in the selected chip foiiiiing region 51 in step S36 (S36: YES), it is determined whether or not the chip foiiiiing region 51 before inspection is present in the wafer 50 (step S38). Since the number of chip forming regions 51 in the wafer 50 can be grasped in advance, the control and analysis device 19 determines whether or not the chip forming region 51 before inspection is present according to whether or not the chip forming region 51 has been selected by the number of chip foixning regions 51 in the wafer 50, for example.

In a case where it is determined that the chip forming region 51 before inspection is present in the wafer 50 in step S38 (S38: NO), one chip forming region 51 before inspection is selected (step S39). Specifically, the control and analysis device 19 specifies the chip forming region 51 to be inspected next according to a predetermined selection order. When the chip forming region 51 is specified, the pin 31 is brought into contact with the pad 74 of the chip forming region 51, the pin 32 is brought into contact with the pad 75, the pin 33 is brought into contact with each pad 76, and the pin 34 is brought into contact with the pad 77. Thereafter, the processing of steps S33 to S38 described above is performed again. On the other hand, in a case where it is determined that the chip forming region 51 before inspection is not present in the wafer 50 in step S38 (S38: YES), the inspection step of step S3 for the wafer 50 is completed.

Returning to FIG. 6, subsequently, dicing (cutting) of the wafer 50 along the dicing street 60 is performed (step S4: dicing step). In the dicing step, the wafer 50 is diced for each chip forming region 51 (refer to FIG. 2). In the present embodiment, respective components (the photodiode 71, the signal processing circuit 72, the PCA 73, and the pads 74, 75, 76, and 77) of the inspection device 70, which is a device for inspecting the operation state of the memory cell 57, are formed on the dicing street 60. For this reason, each component of the inspection device 70 is not included in the chip generated by dicing for each chip forming region 51. Dicing is performed by a dicing apparatus, such as a dicer or a dicing saw, for example. The dicing apparatus performs cutting along the dicing street 60 using, for example, an ultra-thin blade attached to the tip of a spindle that rotates at a high speed.

Finally, a plurality of chips generated by dicing the wafer 50 are assembled (step S5: assembly step). In the assembly step, a semiconductor device assembling step that has been conventionally known is performed. For example, among the chips after dicing, a chip whose operation state is normal (non-defective) in the inspection step of step S3 is picked up, and the chip is mounted on a large substrate and sealed with a sealing resin. The position information of the non-defective chip (chip forming region 51) is stored, for example, by the control and analysis device 19 as described above, and the chip is picked up using the position information. In addition, in the assembly step, a plurality of chips may be stacked for the purpose of increasing the capacity. The above is an example of the semiconductor manufacturing method.

[Operational Effect]

As described above, the wafer 50 according to the first embodiment is a semiconductor wafer having a plurality of chip forming regions 51, and includes the memory cell 57 formed in the chip foaming region 51 and the inspection device 70 formed in the chip forming region 51. The inspection device 70 has the photodiode 71 that receives an input of pump light for checking the operation of the memory cell 57 and outputs an electrical signal corresponding to the pump light and the signal processing circuit 72 that generates a logic signal based on the electrical signal output from the photodiode 71 and outputs the logic signal to the memory cell 57.

In the wafer 50 according to the first embodiment, as the inspection device 70, the photodiode 71 that outputs an electrical signal corresponding to an optical signal and the signal processing circuit 72 that generates a logic signal based on the electrical signal are provided. Since the signal for checking the operation of the memory cell 57 is input as an optical signal, it is not necessary to bring the pin for signal input into contact with the input terminal 53 when inspecting the operation state. For this reason, in an aspect in which the pin for signal input is brought into contact with the terminal of the circuit, an increase in the pressing force on the wafer, which has been a problem when checking the operation state of a high-density integrated circuit, does not become a problem. Then, a logic signal is generated by the signal processing circuit 72 based on the electrical signal output from the photodiode 71, and the logic signal is input to the internal circuit. Accordingly, even in an aspect in which the signal for operation check is input as an optical signal, the operation of the internal circuit is appropriately checked as in the conventional aspect in which the pin is brought into contact with the terminal. In addition, in the aspect in which the pin for signal input is brought into contact with the terminal of the circuit, when checking the operation of a high-density integrated circuit, it is necessary to bring pins into contact with densely provided terminals with high accuracy. For this reason, pin tips need be made fine, but there has been a limitation in physically reducing the pin tips. As a result, there is a possibility that it is not possible to cope sufficiently with an increase in the density of the integrated circuit. In this regard, in the inspection of the operation state of the wafer 50 according to the first embodiment, the signal for operation check is input as an optical signal, and accordingly, the shape of the pin tip does not become a problem when checking the operation. As described above, according to the configuration according to the first embodiment, it is possible to provide a semiconductor wafer suitable for the inspection of the operation state. In addition, in the aspect in which the pin for signal input is physically in contact with the terminal of the circuit, there is an upper limit (for example, several hundred MHz) in the frequency band of the signal that can be supplied by the pin. Depending on the upper limit, there is a case where it is not possible to respond to a high-speed input signal. In this regard, in the case of inspecting the operation state using the wafer 50 according to the present embodiment, the signal for operation check is supplied not by physical contact of pins but by input of an optical signal. Therefore, it is possible to supply a signal in a frequency band exceeding the above-described upper limit as a signal for operation check. In addition, in the wafer 50, since the above-described inspection device 70 is formed in the chip forming region 51, a wiring for electrically connecting the photodiode 71 and the like to the input and output terminals formed on the chip can be shortened. As a result, a semiconductor wafer more suitable as a semiconductor for which operation state inspection is to be performed is provided.

In the first embodiment, the wafer 50 includes the input terminal 53 that is formed in the chip forming region 51 to input an input signal to the memory cell 57 and the output terminal 54 that is formed in the chip forming region 51 to output an output signal from the memory cell 57, and the input terminal 53 and the output terminal 54 are configured to include the through electrodes 53a and 54a that penetrate the wafer 50 in the thickness direction. Since the input terminal 53 and the output terminal 54 are configured to include the through electrodes 53a and 54a, a plurality of chips can be connected to each other without using wire bonding or the like in a configuration in which the plurality of chips are stacked. Thus, the chip on which through electrodes are formed is significant for reducing the number of wirings, such as wire bonding. In the wafer 50, as described above, since the inspection device 70 is also formed in the chip forming region 51, a wiring such as wire bonding relevant to the inspection device 70 can be shortened. Therefore, the effect of the configuration of the semiconductor in which chips are stacked using the through electrodes can be more noticeably achieved. That is, since the inspection device 70 is provided in the chip forming region 51 and the input teiininal 53 and the output terminal 54 are configured to include the through electrodes 53a and 54a, the effect of shortening the wiring such as wire bonding can be more suitably achieved.

In the first embodiment, the wafer 50 includes the output terminal 54 for outputting an output signal from the memory cell 57, and the inspection device 70 has the PCA 73 that is electrically connected to the output teiininal 54 and outputs a signal corresponding to the output signal while the probe light is being input. Thus, since the PCA 73 that outputs a signal corresponding to the output signal is provided, it is possible to detect a signal relevant to the inspection of the operation state of the memory cell 57, without bringing a pin into contact with the output terminal 54 itself, by detecting the signal from the PCA 73. This further suppresses an increase in the pressing force on the semiconductor wafer, which is a problem in the aspect in which pins are brought into contact with terminals. That is, by adopting the configuration in which the PCA 73 is provided, it is possible to provide a semiconductor wafer more suitable for the inspection of the operation state. In addition, since the probe light is pulsed light, the signal itself output from the PCA 73 can be a signal having a narrow frequency band. For this reason, even in a case where the logic signal is a high-speed signal and the band of the output signal output from the output terminal 54 is wide, the signal relevant to the inspection of the operation state of the memory cell 57 (signal output from the PCA 73) can be easily detected using a probe pin or the like. That is, by adopting the configuration in which the PCA 73 is provided, even in a case where a high-speed signal is input, the operation state of the internal circuit is appropriately inspected using a simple configuration capable of detecting only a narrow band signal, such as a probe pin.

In the first embodiment, the signal processing circuit 72 has the amplifier 72a that amplifies the electrical signal output from the photodiode 71 at a predetermined amplification degree and the discriminator 72b that generates a logic signal based on the electrical signal amplified by the amplifier 72a and outputs the logic signal to the memory cell 57. Therefore, in a case where the amount of light received by the photodiode 71 is equal to or greater than a predetermined amount, a configuration in which a logic signal that is High is input to the memory cell 57 can be easily realized by setting the amplification degree of the amplifier 72a and the threshold value of the discriminator 72b. As a result, a semiconductor wafer more suitable as a semiconductor wafer for which operation state inspection is to be performed is provided.

In the first embodiment, in the forming step, the output terminal 54 that is an output terminal for outputting an output signal from the memory cell 57 is further formed so as to correspond to the chip forming region 51. In the inspection step, by inputting the probe light to a region corresponding to the output terminal 54, a signal corresponding to the output signal that is output from the output terminal 54 in response to the input of a logic signal to the memory cell 57 is detected to inspect the operation state of the memory cell 57. Thus, by detecting the signal corresponding to the output signal by inputting the optical signal to the region corresponding to the output terminal 54, a signal relevant to the inspection of the operation state of the internal circuit is detected without bringing the probe pin into contact with the output teiiiiinal 54. This further suppresses an increase in the pressing force on the wafer (in particular, a chip forming region in the wafer), which is a problem in the aspect in which probe pins are brought into contact with terminals. That is, a semiconductor manufacturing method more suitable for increasing the density of the integrated circuit is provided.

In the first embodiment, in the foiiiiing step, the PCA 73 that is electrically connected to the output terminal 54 and outputs a signal corresponding to the output signal while the optical signal is being input is further formed so as to correspond to the chip foiiiiing region 51. In the inspection step, the probe light, which is pulsed light synchronized with the pump light, is repeatedly input to the PCA 73 while changing the delay time with respect to the input timing of the pump light to the photodiode 71, and a signal corresponding to the output signal that is output from the PCA 73 is detected. That is, in the inspection step, the probe light synchronized with the pump light, which is pulsed light continuously output in a predetermined cycle, is delayed by a predetermined delay time with respect to the input timing of the pump light to the photodiode 71 and input to the PCA 73, and the delay time is changed to detect a signal corresponding to the output signal that is output from the PCA 73 in response to the input of each pulse of the probe light. As described above, since the probe light is repeatedly input to the PCA 73 with a delay with respect to the input timing of the pump light to the photodiode 71 and the delay time is changed in the repeated input, the output signal that is output from the output terminal 54 can be sampled. Therefore, the operation state of the internal circuit is appropriately inspected from the sampling result. In a case where the inspection is performed in this manner, the output signal output from the output terminal 54 is not measured as it is, but the output signal is sampled by measuring the signal output from the PCA 73 multiple times. Since the signal output from the PCA 73 (signal corresponding to the output signal) is a signal having a narrow frequency band, the signal output from the PCA 73 (signal corresponding to the output signal) can be easily detected using a probe pin or the like, for example, even in a case where the logic signal is a high-speed signal and the band of the output signal output from the output teiiiiinal 54 is wide. That is, by performing the inspection using the method described above, even in a case where a high-speed signal is input, the operation state of the internal circuit is appropriately inspected using a simple configuration capable of detecting only a narrow band signal, such as a probe pin.

### Second Embodiment

Next, a second embodiment will be described with reference to FIGS. 9 to 11. Hereinafter, differences from the first embodiment will be mainly described.

[Wafer]

As illustrated in FIG. 9, unlike the wafer 50 in the first embodiment, a wafer 50A according to a second embodiment does not have the PCA 73 and a nonlinear optical crystal 150 is disposed on the output terminal 54. In addition, the nonlinear optical crystal 150 does not necessarily need to be in contact with the output terminal 54 but needs to be close to the output terminal 54 to such an extent that a change in the electric field of the output terminal 54 can be detected. At the time of operation state inspection by a wafer inspection apparatus 1A to be described later, the nonlinear optical crystal 150 may be disposed only on the output terminal 54 of the chip forming region 51 under inspection, or may be disposed on the output terminals 54 of all the chip foiiiiing regions 51. In addition, in FIG. 9, for convenience of explanation, illustration of a part of the configuration is omitted. Specifically, in FIG. 9, the amplifier 72a and the discriminator 72b are simply shown as the signal processing circuit 72, and the illustration of the memory block 52 (memory cell 57) is omitted.

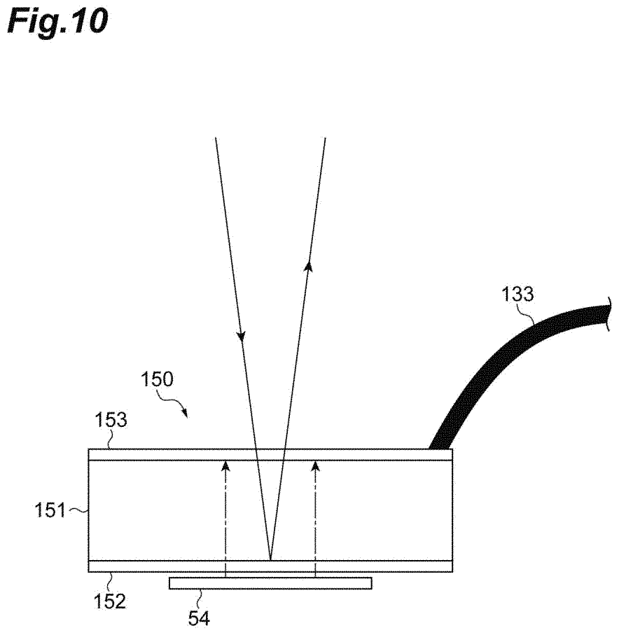

FIG. 10 is a diagram for explaining the reflection of probe light at the nonlinear optical crystal 150 disposed on the output terminal 54. In addition, in FIG. 10, a one-dot chain line indicates an electric field, and a solid line arrow indicates probe light. The nonlinear optical crystal 150 has a crystal portion 151, a probe light reflecting mirror 152, and a transparent electrode 153. In addition, a ground electrode pin 133 is connected to the nonlinear optical crystal 150. The crystal portion 151 is configured to include, for example, ZnTe-based compound semiconductor single crystal. The probe light reflecting mirror 152 is provided on the lower surface side (output terminal 54 side) of the crystal portion 151, and is a mirror that reflects the probe light. The transparent electrode 153 is provided on the upper surface side of the crystal portion 151, and is an electrode serving as a probe light incidence surface. The nonlinear optical crystal 150 is disposed on the output terminal 54. When the electric field on the output terminal 54 changes due to the output signal that is output from the output terminal 54 in response to the logic signal, the electric field leaks to the nonlinear optical crystal 150, and accordingly, the refractive index of the nonlinear optical crystal 150 changes. When the probe light is incident on such a nonlinear optical crystal 150, the polarization state (polarization plane) of reflected light (reflected light of the probe light) reflected by the probe light reflecting mirror 152 changes according to the change in the refractive index. Due to the change in the polarization state (polarization plane) of the reflected light, the amount of light (light intensity) reflected by a beam splitter 12A (polarizing beam splitter) changes. By detecting the change in the light intensity with a photodetector 99, it is possible to determine whether or not a chip on which devices are formed is defective (whether or not the chip is a defective product).

[Wafer Inspection Apparatus]

FIG. 9 is a schematic perspective view illustrating the wafer inspection apparatus 1A according to the second embodiment. The wafer inspection apparatus 1A illustrated in FIG. 9 is an apparatus for inspecting the operation state of the memory cell 57 (internal circuit) formed in the chip forming region 51 of the wafer 50A, similarly to the wafer inspection apparatus 1 of the first embodiment. The wafer inspection apparatus 1A emits pump light to the photodiode 71 of the wafer 50A and emits probe light to the nonlinear optical crystal 150 on the output terminal 54 of the wafer 50A, and inspects the operation state of an internal circuit, such as the memory cell 57, based on reflected light from the nonlinear optical crystal 150. The wafer inspection apparatus 1A has a tester 95, a VCSEL array 96, a probe light source 97, the beam splitter 12A, a wave plate 98, an optical scanner 15A, condensing lenses 16A and 17A, the photodetector 99, a lock-in amplifier 18A, and a control and analysis device 19A.

The tester 95 is operated by a power supply (not illustrated), and repeatedly applies an electrical signal for inspection to the VCSEL array 96 and the probe light source 97. As a result, the VCSEL array 96 and the probe light source 97 generate light beams based on the common electrical signal for inspection, so that the light beams output from the VCSEL array 96 and the probe light source 97 can be synchronized with each other.

The vertical-cavity surface emitting laser (VCSEL) array 96 is a surface emitting laser, and emits laser light as pump light to the plurality of photodiodes 71 simultaneously (in parallel). The VCSEL array 96 generates laser light based on the electrical signal for inspection input from the tester 95. The VCSEL array 96 can perform modulation at, for example, about 40 GBPS, so that an incidence pulse train corresponding to 40 GBPS can be formed. In addition, in the VCSEL array 96, light emitting points are arranged at predetermined pitches (for example, 250 μm). By setting the predetermined pitch as an interval between a plurality of adjacent photodiodes 71, it is possible to emit laser light to the respective photodiodes 71 simultaneously (in parallel). In addition, the pitch between the light emitting points of the VCSEL array 96 does not necessarily match the interval between the photodiodes. For example, in a case where the light emitting points are arranged at a pitch of 250 μm, light may be reduced to ½, ¼, or the like using a lens system, and the light may be emitted to the photodiodes 71 arranged in the shape of an array at a pitch of 125 μm or 62.5 μm. The pump light emitted from the VCSEL array 96 passes through the condensing lens 16A to be emitted to each photodiode 71.

The probe light source 97 is a light source that outputs probe light that is pulsed light emitted to the nonlinear optical crystal 150. The probe light source 97 generates probe light based on the electrical signal for inspection input from the tester 95. The probe light is synchronized with the laser light (pump light) generated in the VCSEL array 96 described above. More specifically, the probe light output from the probe light source 97 is an optical signal that is synchronized with the pump light output from the VCSEL array 96 and delayed by a predetermined time with respect to the pump light. The probe light source 97 repeatedly outputs the probe light while changing the delay time with respect to the pump light, for example, for each pulse. In this case, the probe light source 97 may include an electrical circuit that changes the delay time. In this manner, as in the first embodiment, it is possible to detect a high-speed output pulse (output signal output from the output terminal 54) while performing sampling. In addition, the probe light source 97 may output CW light instead of the pulsed light. In this case, the probe light may not be delayed with respect to the pump light.

The beam splitter 12A is a polarizing beam splitter that is set to transmit light having a polarization component of 0° and reflect light of 90°. The beam splitter 12A transmits light having a polarization component of 0° that is output from the probe light source 97. The probe light transmitted through the beam splitter 12A is emitted to the nonlinear optical crystal 150 through the wave plate 98 that is a λ/8 wave plate, the optical scanner 15A, and the condensing lens 17A. The optical scanner 15A emits probe light according to the control signal from the control and analysis device 19A so that the probe light is emitted to the nonlinear optical crystal 150 on each output terminal 54. In addition, reflected light from the nonlinear optical crystal 150 according to the probe light is input to the beam splitter 12A through the condensing lens 17A, the optical scanner 15A, and the wave plate 98. The reflected light passes through the wave plate 98, which is a λ/8 wave plate, twice to become circularly polarized light. Of the circularly polarized light, reflected light having a polarization component of 90° is reflected by the beam splitter 12A and input to the photodetector 99.

The photodetector 99 is, for example, a photodiode, an avalanche photodiode, a photomultiplier tube, or an area image sensor, and receives the reflected light from the nonlinear optical crystal 150 (signal corresponding to the output signal output from the output terminal 54 in response to the input of a logic signal to the internal circuit) and outputs a detection signal. Only a signal component having a predetermined frequency of the detection signal is amplified by the lock-in amplifier 18A, and the amplified signal is input to the control and analysis device 19A. The control and analysis device 19A generates a waveform (analysis image) based on the amplified signal from the lock-in amplifier 18A. The user can determine whether or not a chip on which devices are formed is defective (whether or not the chip is a defective product) based on the analysis image generated by the control and analysis device 19A, for example.

In addition, an inspection method (inspection of the operation state of an internal circuit, such as the memory cell 57, based on the reflected light from the nonlinear optical crystal 150) of the second embodiment may be executed by the wafer inspection apparatus 1 according to the first embodiment instead of the wafer inspection apparatus 1A illustrated in FIG. 9.

[Wafer Inspection Method]

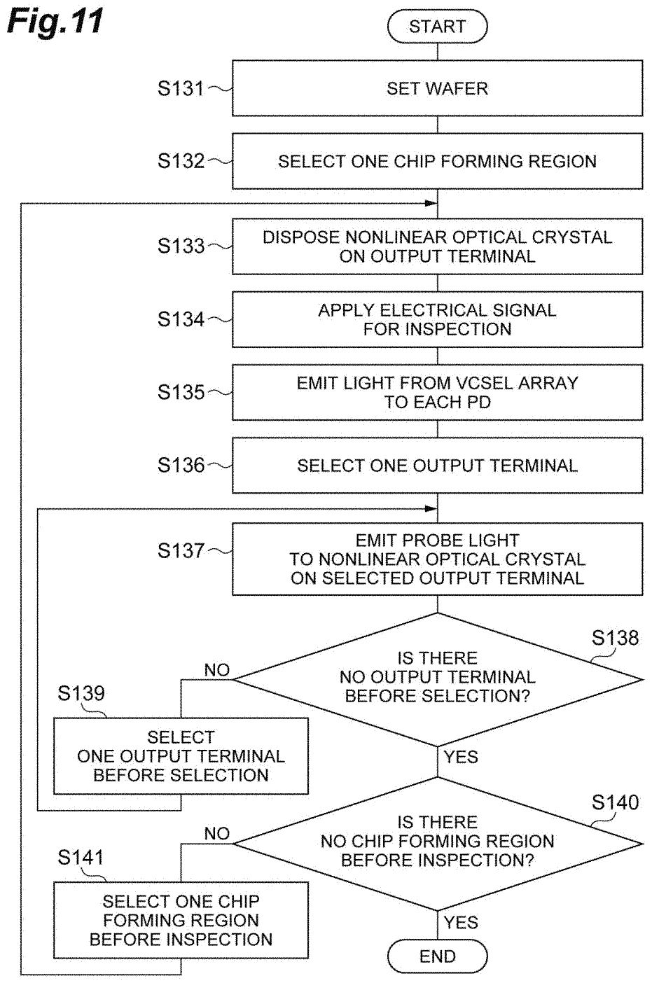

Next, an example of a wafer inspection method using the wafer inspection apparatus 1A described above will be described with reference to the flowchart of FIG. 11. The wafer inspection method is performed in “step S3: inspection step” of FIG. 6 described in the first embodiment.

As illustrated in FIG. 11, first, the wafer 50A on which devices are formed is set on an inspection table (not illustrated) of the wafer inspection apparatus 1A (step S131). Then, one chip forming region 51 is selected from the plurality of chip forming regions 51 included in the wafer 50A (step S132). Specifically, for example, when an instruction to start inspection is received from the user, the control and analysis device 19A specifies the chip forming region 51 at a predetermined position set in advance as the chip forming region 51 to be inspected first. Then, the nonlinear optical crystal 150 is disposed on the output terminal 54 of the selected chip forming region 51 (step S133).

Then, an electrical signal for inspection is applied from the tester 95 to the VCSEL array 96 and the probe light source 97 (step S134). As a result, the VCSEL array 96 and the probe light source 97 generate light beams based on the common electrical signal for inspection, so that the light beams output from the VCSEL array 96 and the probe light source 97 can be synchronized with each other.

Then, laser light as pump light is emitted to the plurality of photodiodes 71 simultaneously (in parallel) (step S135). Specifically, the control and analysis device 19A controls the VCSEL array 96 so that the pump light is emitted to each photodiode 71 in the selected chip forming region 51.

Then, one output terminal 54 is selected from the output terminals 54 of the selected chip forming region 51 (step S136). Specifically, the control and analysis device 19A specifies one output terminal 54 according to a predetermined selection order. Then, the probe light is emitted to the nonlinear optical crystal 150 on the selected output terminal 54 (step S137). Specifically, the control and analysis device 19A controls the probe light source 97 and the optical scanner 15A so that the probe light is emitted to a desired position. The control and analysis device 19A controls the probe light source 97 so that the probe light synchronized with the pump light is input to the nonlinear optical crystal 150 with a delay with respect to the input timing of the pump light to the photodiode 71. Since the nonlinear optical crystal 150 is disposed on the output terminal 54, the electric field changes based on the output signal that is output from the output terminal 54 in response to the logic signal, and as a result, the refractive index changes. When the probe light is incident on such a nonlinear optical crystal 150, the polarization state of reflected light (reflected light of the probe light) reflected by the probe light reflecting mirror 152 changes according to the change in the refractive index. Due to the change in the polarization state of the reflected light, the light intensity output from the beam splitter 12A (polarizing beam splitter) changes. The change in light intensity is received by the photodetector 99, and an analysis image is generated by the control and analysis device 19A based on the detection signal from the photodetector 99. For example, after the end of the inspection of all the chip forming regions 51 of the wafer 50A, the user can check whether or not the operation state of the region of the inspected memory cell 57 is a normal state based on the analysis image.

Then, it is determined whether or not the output terminal 54 before selection is present in the selected chip forming region 51 (step S138). Since the number of output terminals 54 in each chip forming region 51 can be grasped in advance, the control and analysis device 19A determines whether or not the output terminal 54 before selection is present based on whether or not probe light emission corresponding to the number of output terminals 54 in one chip forming region 51 has been performed, for example.

In a case where it is determined that the output terminal 54 before selection is present in the selected chip forming region 51 in step S138 (S138: NO), one output terminal 54 before the selection is selected (step S139). Thereafter, the processing of steps S137 and S138 described above is performed again.

On the other hand, in a case where it is determined that the output terminal 54 before selection is not present in the selected chip for region 51 in step S138 (S138: YES), it is determined whether or not the chip forming region 51 before inspection is present in the wafer 50A (step S140). Since the number of chip forming regions 51 in the wafer 50A can be grasped in advance, the control and analysis device 19A deteiinines whether or not the chip forming region 51 before inspection is present according to whether or not the chip Ruining region 51 has been selected by the number of chip forming regions 51 in the wafer 50A, for example.

In a case where it is determined that the chip forming region 51 before inspection is present in the wafer 50A in step S140 (S140: NO), one chip forming region 51 before inspection is selected (step S141). Specifically, the control and analysis device 19A specifies the chip forming region 51 to be inspected next according to a predetermined selection order. Thereafter, the processing of steps S133 to S140 described above is performed again. On the other hand, in a case where it is determined that the chip forming region 51 before inspection is not present in the wafer 50A in step S140 (S140: YES), “inspection step” for the wafer 50A is completed.

[Operational Effect]

As described above, in the semiconductor manufacturing method according to the second embodiment, in the inspection step, the nonlinear optical crystal 150 is disposed on the output terminal 54, the probe light is input to the nonlinear optical crystal 150, and the reflected light from the nonlinear optical crystal 150 is detected as a signal corresponding to the output signal. The refractive index of the nonlinear optical crystal 150 changes according to the voltage at the output terminal 54 (that is, the voltage of the output signal output from the output terminal 54). For this reason, the polarization state of the reflected light from the nonlinear optical crystal 150 changes according to the voltage of the output signal output from the output terminal 54. By detecting such a change in polarization state as a change in light intensity through the beam splitter 12A, it becomes possible to inspect the operation state of the internal circuit according to the intensity of the reflected light. By performing the inspection using the method described above, the operation state of the internal circuit is appropriately inspected using only a simple configuration relevant to the detection of reflected light without bringing probe pins and the like into contact with the wafer 50A.

### Third Embodiment

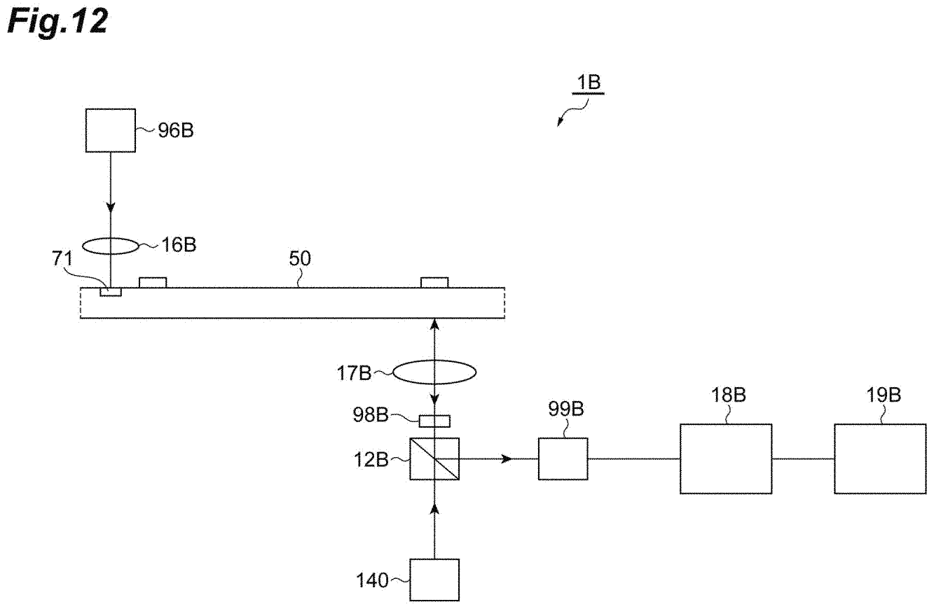

Next, a third embodiment will be described with reference to FIGS. 12 to 14. Hereinafter, differences from the first and second embodiments will be mainly described.

[Wafer Inspection Apparatus]

FIG. 12 is a schematic diagram of a wafer inspection apparatus 1B according to a third embodiment. The wafer inspection apparatus 1B illustrated in FIG. 12 is an apparatus for inspecting the operation state of the memory cell 57 (internal circuit) formed in the chip forming region 51 of the wafer 50, similarly to the wafer inspection apparatus 1 of the first embodiment and the like. The wafer inspection apparatus 1B emits pulsed light to the photodiode 71 of the wafer 50 and emits probe light (CW or pulsed light) from an opposite side (back surface side) to the surface of the wafer 50 on which the photodiode 71 is formed, and inspects the operation state of an internal circuit, such as the memory cell 57, based on the light emitted from the back surface side.

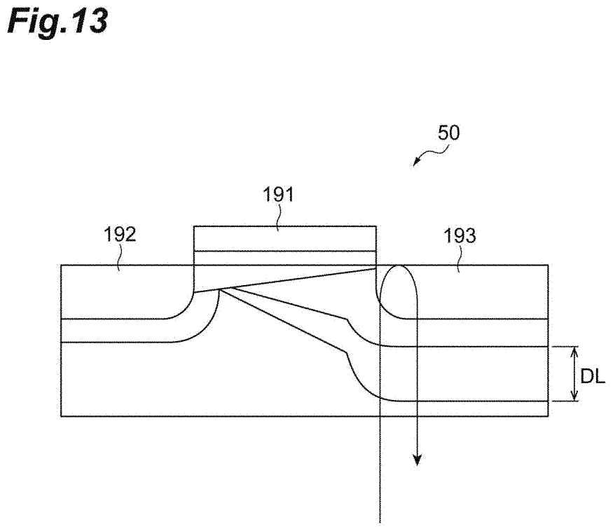

FIG. 13 is a diagram for explaining a change in reflectance according to expansion and contraction of a depletion layer. As illustrated in FIG. 13, the wafer 50 is configured to include a FET including a gate 191, a source 192, and a drain 193. A depletion layer DL of the FET expands and contracts according to High/Low of the logic signal input to the memory cell 57 to change its thickness. For this reason, the operation state of the internal circuit can be inspected by detecting a change in the thickness of the depletion layer DL. Here, the change in the thickness of the depletion layer DL can be detected based on a change in the intensity of reflected light when light is emitted from the back surface side of the wafer 50 (change in the intensity of reflected light according to a change in reflectance according to a change in the thickness of the depletion layer DL). Focusing on this, in the wafer inspection apparatus 1B of the present embodiment, the probe light is emitted from the back surface side of the wafer 50, and the probe light passes through the depletion layer and is reflected from the surface of the device to detect light emitted from the back surface side.

Returning to FIG. 12, the wafer inspection apparatus 1 has a VCSEL array 96B, a probe light source 140, a beam splitter 12B, a wave plate 98B, condensing lenses 16B and 17B, a photodetector 99B, a lock-in amplifier 18B, and a control and analysis device 19B.

The VCSEL array 96B emits laser light (pulsed light) to the plurality of photodiodes 71 simultaneously (in parallel). The VCSEL array 96B is provided at a position where the pulsed light can be emitted to the photodiodes 71. The pulsed light emitted from the VCSEL array 96B passes through the condensing lens 16B to be emitted to each photodiode 71. The probe light source 140 emits the probe light (second optical signal) to a side of the back surface that is a surface of the wafer 50 opposite to a surface on which the photodiode 71 is formed. The probe light source 140 is provided at a position where the probe light can be emitted to the back surface of the wafer 50 (that is, the back surface side of the wafer 50).

The beam splitter 12B is a polarizing beam splitter that is set to transmit light having a polarization component of 0° and reflect light of 90°. The beam splitter 12B transmits light having a polarization component of 0° that is output from the probe light source 140. The probe light transmitted through the beam splitter 12B is emitted to the back surface side of the wafer 50 through the wave plate 98B, which is a λ/8 wave plate, and the condensing lens 17B. In addition, reflected light from the back surface side of the wafer 50 according to the probe light is input to the beam splitter 12B through the condensing lens 17B and the wave plate 98B. The reflected light passes through the wave plate 98B, which is a λ/8 wave plate, twice to become circularly polarized light. Of the circularly polarized light, reflected light having a polarization component of 90° is reflected by the beam splitter 12B and input to the photodetector 99B.

The photodetector 99B receives the reflected light and outputs a detection signal. Only a signal component having a predetermined frequency of the detection signal is amplified by the lock-in amplifier 18B, and the amplified signal is input to the control and analysis device 19B. The control and analysis device 19B generates a waveform (analysis image) based on the amplified signal from the lock-in amplifier 18B. The user can determine whether or not a chip on which devices are formed is defective (whether or not the chip is a defective product) based on the analysis image generated by the control and analysis device 19B, for example.

[Wafer Inspection Method]

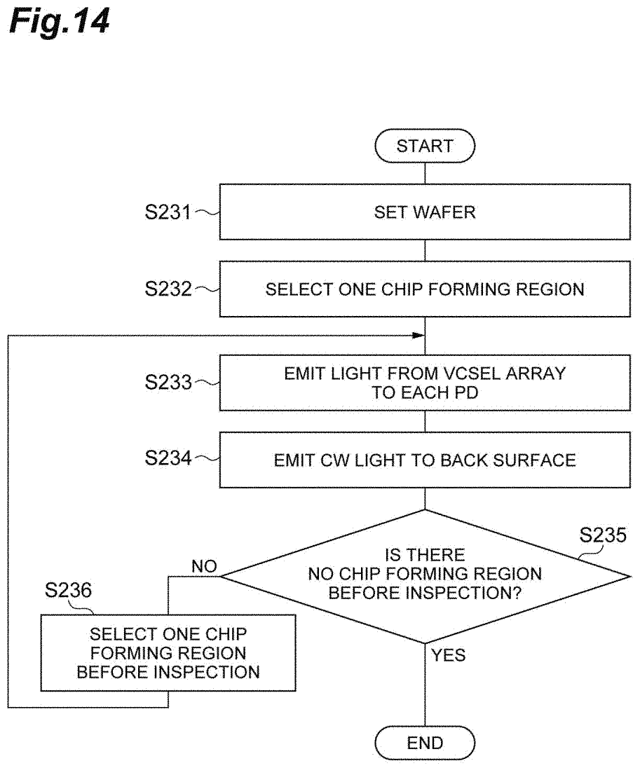

Next, an example of a wafer inspection method using the wafer inspection apparatus 1B described above will be described with reference to the flowchart of FIG. 14. The wafer inspection method is performed in “step S3: inspection step” of FIG. 6 described in the first embodiment.

As illustrated in FIG. 14, first, the wafer 50 on which devices are formed is set on an inspection table (not illustrated) of the wafer inspection apparatus 1B (step S231). Then, one chip foiiiiing region 51 is selected from the plurality of chip forming regions 51 included in the wafer 50 (step S232). Specifically, for example, when an instruction to start inspection is received from the user, the control and analysis device 19B specifies the chip forming region 51 at a predetermined position set in advance as the chip forming region 51 to be inspected first.

Then, laser light from the VCSEL array 96B is emitted to the plurality of photodiodes 71 simultaneously (in parallel) (step S233). Specifically, the control and analysis device 19B controls the VCSEL array 96B so that the laser light is emitted to each photodiode 71 in the selected chip forming region 51.

Then, the probe light is emitted to a side of the back surface that is a surface of the wafer 50 opposite to a surface on which the photodiode 71 is formed (step S234). Specifically, the control and analysis device 19B controls the probe light source 140 so that the probe light is emitted from the back surface side of the wafer 50. The depletion layer DL (refer to FIG. 13) of the wafer 50 expands and contracts according to High/Low of the logic signal input to the memory cell 57 to change its thickness, and the change in the thickness can be detected based on a change in the intensity of reflected light when light is emitted to the back surface side of the wafer 50. The reflected light is received by the photodetector 99B, and an analysis image is generated by the control and analysis device 19B based on the detection signal from the photodetector 99. For example, after the end of the inspection of all the chip forming regions 51 of the wafer 50, the user can check whether or not the operation state of the region of the inspected memory cell 57 is a noiiiial state based on the analysis image.

Then, it is determined whether or not the chip forming region 51 before inspection is present in the wafer 50 (step S235). Since the number of chip forming regions 51 in the wafer 50 can be grasped in advance, the control and analysis device 19B determines whether or not the chip forming region 51 before inspection is present according to whether or not the chip forming region 51 has been selected by the number of chip forming regions 51 in the wafer 50, for example. In a case where it is determined that the chip forming region 51 before inspection is present in the wafer 50 in step S235 (S235: NO), one chip foiming region 51 before inspection is selected (step S236). Specifically, the control and analysis device 19B specifies the chip forming region 51 to be inspected next according to a predetermined selection order. Thereafter, the processing of steps S233 to S235 described above is performed again. On the other hand, in a case where it is determined that the chip forming region 51 before inspection is not present in the wafer 50 in step S235 (S235: YES), “inspection step” for the wafer 50 is completed.

[Operational Effect]

As described above, in the semiconductor manufacturing method according to the third embodiment, in the inspection step, the probe light is input to the surface of the wafer 50 opposite to the surface on which the photodiode 71 is formed, and reflected light from the surface on the opposite side is detected to inspect the operation state of the memory cell 57. When the logic signal is input to the memory cell 57, the thickness of the depletion layer in the chip changes. Such a change in the thickness of the depletion layer can be detected by a change in the intensity of reflected light when the optical signal is input from the back surface (surface opposite to the surface on which the photodiode 71 is formed). Therefore, by detecting the reflected light from the back surface, the operation state of the internal circuit can be appropriately inspected without using a probe pin or the like. In addition, since the VCSEL array 96B is provided on a side where the photodiode 71 is formed and the probe light source 140 is provided on the opposite side, it is possible to appropriately secure the installation space for each light source with a margin.

<Modification Examples>

While the embodiments of the present invention have been described above, the present invention is not limited to the first to third embodiments.

For example, although the explanation has been given on the assumption that the memory cell 57 is formed as an internal circuit in the chip forming region 51, the present invention is not limited to this, and a logic circuit such as a microprocessor, an application processor (high-density integrated circuit) such as a large scale integration (LSI), a mixed integrated circuit in which a memory cell and a logic circuit are combined, or a special-purpose integrated circuit such as a gate array or a cell-based IC may be formed as an internal circuit in the chip forming region.

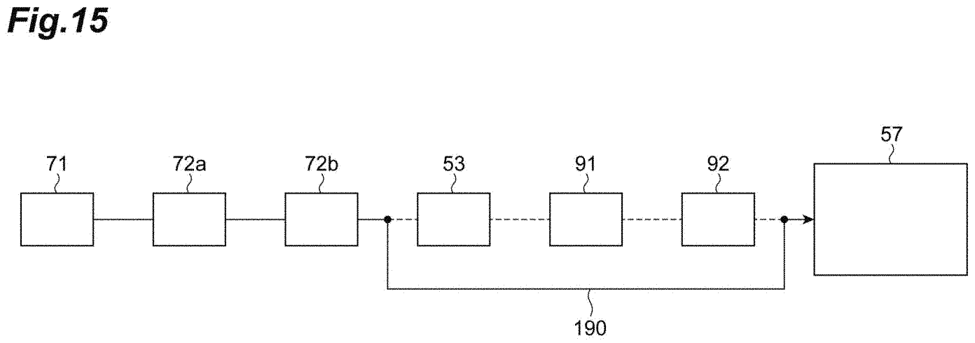

In addition, although the electrical signal transmission path from the photodiode 71 to the memory cell 57 has been described with reference to FIG. 5, the electrical signal transmission path from the photodiode to the memory cell (internal circuit) is not limited to that illustrated in FIG. 5. That is, in the example illustrated in FIG. 5, the explanation has been given on the assumption that the electrical signal output from the photodiode 71 is input to the memory cell 57 through the amplifier 72a, the discriminator 72b, the input terminal 53, the ESD prevention circuit 91, and the signal buffer circuit 92. However, the present invention is not limited to this, and as illustrated in FIG. 15, the logic signal output from the discriminator 72b may be input directly to the memory cell 57 without passing through the input terminal 53 and the like. That is, the discriminator 72b of the signal processing circuit 72 may be connected to the memory cell 57 through a wiring 190 that bypasses the input terminal 53 so that the logic signal is input to the memory cell 57 without passing through the input terminal 53. According to such a configuration, when checking the operation of the internal circuit, the capacity of the input terminal is not a problem, and a high-speed electrical signal can be easily input to the internal circuit.

In addition, although the aspect has been described in which the signal relevant to the inspection of the operation state of the internal circuit is detected without bringing the pin into contact with the output terminal, the present invention is not limited to this, and the pin may be brought into contact with the output teiiiiinal to detect the signal. Also in this case, since the input of the signal for checking the operation of the internal circuit is performed by an optical signal (no pin is brought into contact with the terminal of the circuit on the input side), the pressing force and the like on the wafer can be reduced compared with the related art.

### REFERENCE SIGNS LIST

50, 50A: wafer, 51: chip forming region, 53: input terminal, 54: output terminal, 57: memory cell (internal circuit), 60: dicing street, 70: inspection device, 71: photodiode (light receiving element), 72: signal processing circuit, 72a: amplifier, 72b: discriminator, 150: nonlinear optical crystal, 53a, 54a: through electrode.

1. A semiconductor wafer having a plurality of chip forming regions, comprising:
an internal circuit configured to be formed in each of the chip forming regions; and
an inspection device configured to be formed in each of the chip forming regions,
wherein the inspection device has:
a light receiving element configured to receive an input of a first optical signal for checking an operation of the internal circuit and output an electrical signal corresponding to the first optical signal; and
a signal processing circuit configured to generate a logic signal based on the electrical signal output from the light receiving element and output the logic signal to the internal circuit.

2. The semiconductor wafer according to claim 1, further comprising:
an input terminal configured to be formed in each of the chip forming regions and input an input signal to the internal circuit; and
an output terminal configured to be formed in each of the chip forming regions and output an output signal from the internal circuit,
wherein each of the input terminal and the output terminal is configured to include a through electrode that penetrates the semiconductor wafer in a thickness direction.

3. The semiconductor wafer according to claim 1, further comprising:
an output terminal configured to be formed in each of the chip forming regions and output an output signal from the internal circuit,
wherein the inspection device further has a switch unit configured to be electrically connected to the output terminal and output a signal corresponding to the output signal while a second optical signal is being input.

4. The semiconductor wafer according to claim 1,
wherein the signal processing circuit has:
an amplifier configured to amplify the electrical signal output from the light receiving element at a predetermined amplification degree; and
a discriminator configured to generate the logic signal based on the electrical signal amplified by the amplifier and output the logic signal to the internal circuit.

5. The semiconductor wafer according to claim 1, further comprising:
an input terminal configured to be formed in each of the chip forming regions and input an input signal to the internal circuit,
wherein the signal processing circuit is connected to the internal circuit through a wiring that bypasses the input terminal so that the logic signal is input to the internal circuit without passing through the input terminal.
